(19) United States
(12) Patent Application Publication
(10) Pub. No.: US 2026/0171020 A1
(43) Pub. Date: Jun. 18, 2026

(54) DISPLAY APPARATUS

(71) Applicant: LG Display Co., Ltd., Seoul (KR)

(72) Inventors: Jong Ho KIM, Paju-si (KR); Seung Chan CHOI, Paju-si (KR); Jeong Yeop LEE, Paju-si (KR); Jung Seok SEO, Paju-si (KR); Kyung Chul OK, Paju-si (KR); Woo Seok JEONG, Paju-si (KR)

(73) Assignee: LG Display Co., Ltd., Seoul (KR)

(21) Appl. No.: 19/371,516

(22) Filed: Oct. 28, 2025

(30) Foreign Application Priority Data
Dec. 16, 2024 (KR) 10-2024-0187375

(51) Int. Cl. G09G 3/3233; H10K 59/131; H10K 59/35

(52) U.S. Cl. CPC G09G 3/3233; H10K 59/131; H10K 59/353; G09G 2300/0452; G09G 2300/0842; G09G 2300/0861; G09G 2320/045; G09G 2330/021

(57) ABSTRACT

A display apparatus in one or more examples includes a display panel including unit pixels, each including a first subpixel for emitting light of a first color and a second subpixel for emitting light of a second color different from the first color, and a power supply configured to supply a first driving voltage through a first power line connected to the first subpixels of the unit pixels and supply a second driving voltage through a second power line connected to the second subpixels of the unit pixels. Each of the first and second power lines includes a mesh structure line, the mesh structure line of one of the first and second power lines is electrically disconnected from the mesh structure line of another one of the first and second power lines, and the first driving voltage has a level different from a level of the second driving voltage.

### CROSS-REFERENCE TO RELATED APPLICATIONS

This application claims the benefit of and priority to the Korean Patent Application No. 10-2024-0187375 filed on Dec. 16, 2024, the entire contents of which are incorporated herein by reference for all purposes as if fully set forth herein.

### BACKGROUND

### 1. Technical Field

The present disclosure relates to a display apparatus, and more particularly, for example, without limitation, to a display apparatus where power consumption may be reduced.

### 2. Discussion of Related Art

As information technology advances, the market for display apparatuses which are connection mediums connecting a user with information is increasing. Therefore, the use of display apparatuses such as light emitting display apparatuses, quantum dot display (QDD) apparatuses, and liquid crystal display (LCD) apparatuses is increasing.

The display apparatuses described above include a display panel which includes a plurality of subpixels, a driver which outputs a driving signal for driving the display panel, and a power supply which generates power which is to be supplied to the display panel or the driver.

In such display apparatuses, when the driving signal (for example, a scan signal and a data signal) is supplied to each of the subpixels provided in the display panel, a selected subpixel may transmit light or may self-emit light, and thus, an image may be displayed.

In the related art, each of subpixels emitting red (R) light, green (G) light, and blue (B) light may be supplied with a high-level driving voltage through a power line including one mesh structure line.

The description of related art should not be considered prior art merely because it is mentioned in or associated with this section. The description of related art includes information that describes one or more aspects of the subject technology, and the description in this section does not limit the scope of the invention.

### SUMMARY

Example embodiments of the present disclosure provide a display apparatus where power consumption may be reduced.

Example embodiments of the present disclosure provide a display apparatus which may prevent or mitigate a degradation in a driving transistor included in each subpixel.

Example embodiments of the present disclosure provide a display apparatus which may enhance reliability and may reduce power consumption, thereby supporting environmental, social and governance (ESG) initiatives.

Aspects according to the present disclosure are not limited to the above-mentioned aspect. Other aspects and advantages according to the present disclosure that are not mentioned may be understood based on following descriptions, and may be more clearly understood based on embodiments according to the present disclosure. Further, it will be easily understood that the aspects and advantages according to the present disclosure may be realized using means shown in the claims or combinations thereof.

To achieve these and other advantages and in accordance with one or more aspects of the disclosure, as embodied and broadly described herein, a display apparatus includes a display panel including a plurality of unit pixels, each unit pixel including a first subpixel for emitting light of a first color and a second subpixel for emitting light of a second color different from the first color, and a power supply configured to supply a first driving voltage through a first power line connected to the first subpixels of the plurality of unit pixels and supply a second driving voltage through a second power line connected to the second subpixels of the plurality of unit pixels, wherein each of the first power line and the second power line includes a mesh structure line, the mesh structure line of one of the first power line and the second power line is electrically disconnected from the mesh structure line of another one of the first power line and the second power line, and the first driving voltage has a level different from a level of the second driving voltage.

The plurality of unit pixels may thereby include the first subpixels and the second subpixels. Each of the first power line and the second power line may include a plurality of power lines. Each mesh structure line may include a plurality of lines.

The mesh structure line of the first power line may be connected to the first subpixels and may include a plurality of first horizontal lines parallel to a horizontal direction of the display panel and a plurality of first vertical lines parallel to a vertical direction of the display panel, and the mesh structure line of the second power line may be connected to the second subpixels and may include a plurality of second horizontal lines parallel to the horizontal direction of the display panel and a plurality of second vertical lines parallel to the vertical direction of the display panel.

The plurality of first horizontal lines and the plurality of first vertical lines of the first power line may be electrically connected to each other, the plurality of second horizontal lines and the plurality of second vertical lines of the second power line may be electrically connected to each other, and each of the plurality of first horizontal lines and the plurality of first vertical lines may be insulated from each of the plurality of second horizontal lines and the plurality of second vertical lines.

The plurality of first horizontal lines may be disposed on a layer that is different from a layer on which the plurality of first vertical lines are disposed, and the plurality of second horizontal lines may be disposed on a layer that is different from a layer on which the plurality of second vertical lines are disposed.

One of the plurality of first vertical lines and one of the plurality of second vertical lines may be disposed on a same layer in a unit pixel and may be spaced apart from each other in the horizontal direction.

One of the plurality of first horizontal lines and one of the plurality of second horizontal lines may be disposed on a same layer in a unit pixel and may be spaced apart from each other in the vertical direction.

One of the plurality of first vertical lines and one of the plurality of second vertical lines may be disposed apart from each other on a first planarization layer covering a plurality of transistors included in a unit pixel, and one of the plurality of first horizontal lines and one of the plurality of second horizontal lines may be disposed apart from each other on a second planarization layer covering the one of the plurality of first vertical lines, the one of the plurality of second vertical lines, and the first planarization layer.

Each of the plurality of unit pixels may include a first contact point and a second contact point, at each first contact point, a corresponding one of the plurality of first horizontal lines and a corresponding one of the plurality of first vertical lines may cross each other and may be electrically connected to each other, and at each second contact point, a corresponding one of the plurality of second horizontal lines and a corresponding one of the plurality of the second vertical lines may cross each other and may be electrically connected to each other.

Each of the first and second contact points may overlap a bank defining an emission region of a corresponding one of the first and second subpixels.

At each first contact point, the corresponding one of the plurality of first horizontal lines and the corresponding one of the plurality of first vertical lines may be electrically connected to each other through a second planarization layer, and at each second contact point, the corresponding one of the plurality of second horizontal lines and the corresponding one of the plurality of the second vertical lines may be electrically connected to each other through the second planarization layer.

A respective one of the plurality of first horizontal lines may be insulated from a respective one the plurality of second vertical lines at an intersection point therebetween in each of the plurality of unit pixels, and a respective one of the plurality of second horizontal lines may be insulated from a respective one of the plurality of first vertical lines at an intersection point therebetween in each of the plurality of unit pixels.

Each first subpixel may include a light emitting device for emitting red light, each second subpixel may include a light emitting device for emitting green light, the power supply may be configured to supply the first driving voltage to the light emitting devices of the first subpixels and supply the second driving voltage to the light emitting devices of the second subpixels, and the level of the first driving voltage may be lower than the level of the second driving voltage. The plurality of unit pixels may include the light emitting devices of the first subpixels and the light emitting devices of the second subpixels.

Each of the plurality of unit pixels may include a third subpixel, each of the third subpixels of the plurality of unit pixels may include a light emitting device for emitting light of a third color different from the first and second colors, the power supply may be further configured to supply a third driving voltage, having a level different from the level of each of the first and second driving voltages, to the light emitting devices of the third subpixels through a third power line, and the third power line may include a mesh structure line electrically disconnected from the first and second power lines. The plurality of unit pixels may include the first subpixels, the second subpixels, and the third subpixels. The first, second and third power lines may include the mesh structure lines.

The level of each of the first, second and third driving voltages may be set based on a saturation voltage of a driving transistor included in a corresponding one of the first, second and third subpixels.

The first driving voltage may be higher than or equal to the saturation voltage of the driving transistor of the corresponding one of the first subpixels, the second driving voltage may be higher than or equal to the saturation voltage of the driving transistor of the corresponding one of the second subpixels, and the third driving voltage may be higher than or equal to the saturation voltage of the driving transistor of the corresponding one of the third subpixels.

The mesh structure line of the third power line may be connected to the third subpixels and may include a plurality of third horizontal lines parallel to the horizontal direction of the display panel and a plurality of third vertical lines parallel to the vertical direction of the display panel.

The plurality of third horizontal lines and the plurality of third vertical lines of the third power line may be electrically connected to each other, the plurality of third horizontal lines may be insulated from the plurality of first horizontal lines and the plurality of second horizontal lines, and the plurality of third vertical lines may be insulated from the plurality of first vertical lines and the plurality of second vertical lines.

The plurality of third horizontal lines may be disposed on a layer that is different from a layer on which the plurality of third vertical lines may be disposed, the plurality of third horizontal lines may be disposed on a same layer as the plurality of first horizontal lines and the plurality of second horizontal lines, and the plurality of third horizontal lines may be spaced apart from one another in the vertical direction.

The plurality of third horizontal lines may be disposed apart from the plurality of first horizontal lines and the plurality of second horizontal lines in the vertical direction, and the plurality of third horizontal lines may be disposed on a second planarization layer covering the plurality of first, second and third vertical lines and a first planarization layer covering a plurality of transistors included in a unit pixel.

The plurality of third vertical lines may be disposed on a same layer as the plurality of first and second vertical lines in the plurality of unit pixels, the plurality of third vertical lines may be spaced apart from one another in the horizontal direction, and the plurality of third vertical lines may be disposed apart from the plurality of first and second vertical lines on a first planarization layer covering a plurality of transistors included in the plurality of unit pixels.

Each of the plurality of unit pixels further may include a third contact point, at each third contact point, a corresponding one of the plurality of third horizontal lines and a corresponding one of the plurality of third vertical lines may intersect, each third contact point may overlap a bank defining an emission region of a corresponding one of the third subpixels, and at each third contact point, the corresponding one of the plurality of third horizontal lines and the corresponding one of the plurality of third vertical lines may be electrically connected to each other through a second planarization.

A respective one of the plurality of third horizontal lines may be insulated from a respective one of the plurality of first vertical lines at a point intersecting the respective one of the plurality of first vertical lines and insulated from a respective one of the plurality of second vertical lines at a point intersecting the respective one of the plurality of second vertical lines, in each of the plurality of unit pixels.

The light of the third color may be blue light, and the level of the third driving voltage may be higher than the level of each of the first and second driving voltages.

To achieve these and other advantages and in accordance with one or more aspects of the disclosure, as embodied and broadly described herein, a display apparatus includes a display panel including a plurality of unit pixels, each unit pixel including a plurality of subpixels for emitting light of different colors, and a power supply configured to supply a plurality of driving voltages through a plurality of power lines connected to the plurality of subpixels. Each of the plurality of power lines may include a mesh structure line, the mesh structure lines of the plurality of power lines may be electrically disconnected from one another, and the plurality of driving voltages may have different levels. The plurality of power lines may include the mesh structure lines.

A level of each of the plurality of driving voltages may be set based on a saturation voltage of a driving transistor included in a corresponding one of the plurality of subpixels.

In one or more example embodiments of the present disclosure, first and second power lines electrically disconnected from each other may be connected to first and second subpixels which emit lights of different colors, and first and second driving voltages, which are different from each other, may be supplied through the first and second power lines, and thus, the power consumption of a display apparatus may decrease, and a degradation in a driving transistor included in each of the first and second subpixels may be prevented or mitigated.

In one or more example embodiments of the present disclosure, because each of the first and second power lines includes a mesh structure line, even when a portion of each of the first and second power lines is open-circuited (or disconnected) by a foreign material, the first and second driving voltages may be supplied to the first and second subpixels, and thus, the display apparatus may be stably driven.

The example embodiments of the present disclosure may decrease the power consumption of the display apparatus, thereby supporting ESG initiatives.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a diagram for illustrating an example embodiment of a display apparatus applicable to the present disclosure;

FIG. 2 is an example diagram for illustrating an example embodiment of a pixel equivalent circuit applicable to each subpixel of FIG. 1;

FIG. 3 is a diagram for illustrating a connection structure of first, second, and third power lines which are electrically disconnected from one another and have a mesh structure line, according to an example embodiment of the present disclosure;

FIGS. 4(a) and 4(b) are example diagrams for describing a saturation voltage of a driving transistor electrically connected to a light emitting device emitting red (R) light, green (G) light, or blue (B) light in each subpixel;

FIG. 5 is a diagram for illustrating an example embodiment of a cross-sectional surface of a display apparatus taken along line CS0-CS0′ in a diagonal direction with respect to a horizontal direction and a vertical direction in FIG. 3;

FIG. 6 is a diagram for illustrating an example embodiment of a cross-sectional surface of a display apparatus taken along line CS1-CS1′ parallel to a horizontal direction in FIG. 3; and

FIG. 7 is a diagram for illustrating an example embodiment of a cross-sectional surface of a display apparatus taken along line CS2-CS2′ parallel to a vertical direction in FIG. 3.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, electrodes, structures, transistors, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, electrodes, structures, transistors, sections, members, parts, regions, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, components, electrodes, structures, transistors, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

The expression that an element (e.g., layer, film, component, electrode, structure, transistor, section, member, part, region, area, portion, or the like) “is engaged” with another element may be understood, for example, as that the element may be either directly or indirectly engaged with the another element. The term “is engaged” or similar expressions may refer to a term such as “covers,” “surrounds,” “is in contact,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally. For example, the terms, such as a row direction, a column direction, a left-right direction, an up-down direction, a diagonal direction, a first direction, a second direction, a third direction, a horizontal direction x, a vertical direction y, a thickness direction z, a planar direction, a lengthwise direction, a widthwise direction, and a height direction, should not be interpreted only based on a geometrical relationship in which the respective directions are parallel, perpendicular, diagonal, or slanted with respect to each other, and may be meant as directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “at least some portions,” “at least some parts,” “at least a portion,” “at least one or more portions,” “at least a part,” “at least one or more parts,” “at least some elements,” “one or more,” or the like of a plurality of elements can represent (i) one element of the plurality of elements, (ii) a portion (or a part) of the plurality of elements, (iii) one or more portions (or parts) of the plurality of elements, (iv) multiple elements of the plurality of elements, or (v) all of the plurality of elements. Moreover, “at least some,” “at least some portions,” “at least some parts,” “at least a portion,” “at least one or more portions,” “at least a part,” “at least one or more parts,” or the like of an element can represent (i) a portion (or a part) of the element, (ii) one or more portions (or parts) of the element, (iii) the element, or (iv) all portions of the element.

The expression of a first element, a second elements “and/or” a third element should be understood as any one of the first, second and third elements or as any or all combinations of the first, second and third elements. Similar interpretations apply to the use of “and/or” with two elements or with more than three elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

A phrase “substantially the same” or “nearly the same” may indicate a degree of being considered as being equivalent to each other taking into account minute differences due to errors in the manufacturing process.

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein. For example, the term “part” or “unit” may apply, for example, to a separate circuit, component or structure, an integrated circuit, a computational block of a circuit device, or a structure configured to perform a described function as should be understood by one of ordinary skill in the art.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same or similar elements may be illustrated in other drawings, and like reference numerals may refer to like elements unless stated otherwise. The same or similar elements may be denoted by the same reference numerals even though they are depicted in different drawings. Repetitive descriptions of the same or similar elements may be omitted for brevity, and the descriptions provided for elements in one or more figures may also apply to elements in other figures that use the same or similar reference numerals unless stated otherwise. In addition, for the convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

In description of flow of a signal, for example, when a signal is provided from a node A to a node B, this may include a case where the signal is transferred from the node A to the node B via one or more nodes unless a phrase such as “immediately transferred,” “directly transferred” or the like is used.

Hereinafter, a display apparatus according to one or more example embodiments of the present disclosure will be described with reference to the accompanying drawings.

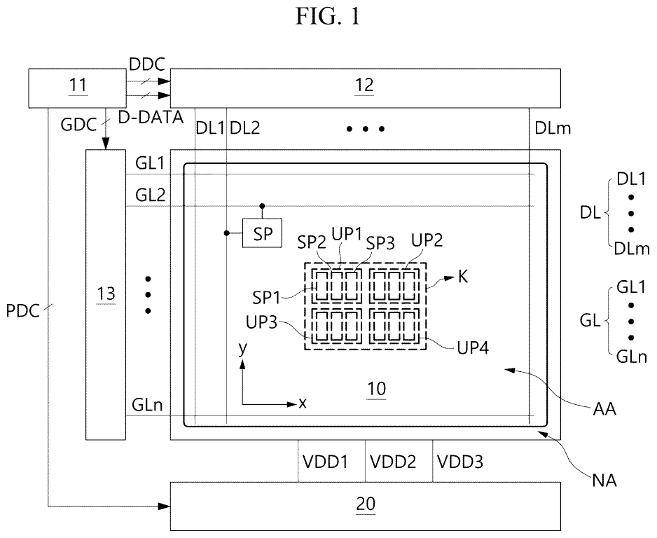

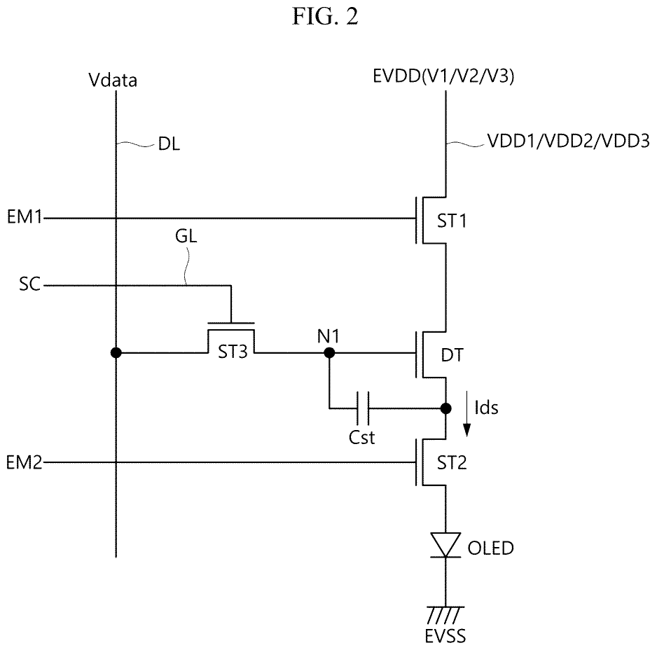

FIG. 1 is a diagram for illustrating an example embodiment of a display apparatus applicable to the present disclosure, and FIG. 2 is an example diagram for illustrating an example embodiment of a pixel equivalent circuit applicable to each subpixel of FIG. 1.

As illustrated in FIG. 1, a display apparatus according to an example embodiment of the present disclosure may include a display panel 10, a timing controller 11, a data driver 12, a gate driver 13, and a power supply 20.

In FIG. 1, a case where the timing controller 11, the data driver 12, the gate driver 13, and the power supply 20 are separately provided is illustrated for example, but unlike FIG. 1, all or some of the timing controller 11, the data driver 12, and the power supply 20 may be integrated into a drive integrated circuit (IC). In FIG. 1, the data driver 12, the gate driver 13, and the power supply 20 may configure a panel driving circuit for driving the display panel 10.

In FIG. 1, a case where the gate driver 13 is provided separately from the display panel 10 is illustrated for example, but the present disclosure is not limited thereto and the gate driver 13 may be provided in a non-active area NA of the display panel 10 and may be directly formed on a substrate of the display panel 10 in a gate driver in panel (GIP) type.

The display panel 10 may include an active area AA and a non-active area NA.

The non-active area NA may be an area outside of the active area AA, and also be referred to as an edge area or a bezel area. All or a portion of the non-active area NA may be an area visible from the front surface of the display apparatus, or an area that is bent and invisible from the front surface of the display apparatus.

The active area AA may be an area which displays an image. A plurality of subpixels SP may be disposed in the active area AA, and the active area AA may display an image by using the plurality of subpixels SP. An area where the plurality of subpixels SP are disposed may be the active area AA, and an area other than the active area AA may be the non-active area NA.

The plurality of subpixels SP disposed in the active area AA, for example, may emit lights of different colors such as red (R), green (G), and blue (B), but is not limited thereto. In another example embodiment, plurality of subpixels SP may include a cyan subpixel, a magenta subpixel and a yellow subpixel. For example, the plurality of subpixels SP may include a plurality of subpixels, such as first to third subpixels SP1 to SP3 which emit lights of different colors. The first to third subpixels SP1 to SP3 may be grouped for each of a plurality of unit pixels (for example, UP1 to UP4), but is not limited thereto. The four unit pixels UP1 to UP4 are described as an example, and are not intended to limit the present disclosure. In other examples, more or less unit pixels may be included.

Also, each of the plurality of unit pixels may include a plurality of subpixels which emit lights of different color, such as two subpixels, three subpixels or four subpixels, or the like. The first to third subpixels SP1 to SP3 mentioned above are only described as an example, and are not intended to limit the present disclosure. In other examples, more or less unit subpixels may be included. For example, each of the plurality of unit pixels may include a first subpixel and a second subpixel.

In a case where a pixel group for color expression is defined as a unit pixel, each unit pixel (for example, UP1 to UP4) may be configured to include, for example, a first subpixel SP1 emitting red (R) light, a second subpixel SP2 emitting green (G) light, and a third subpixel SP3 emitting blue (B) light, and moreover, may be configured to further include a subpixel emitting white light, in addition to the first to third subpixels SP1 to SP3. Accordingly, each unit pixel (for example, UP1 to UP4) may implement a color where colors of lights emitted by the first to third subpixels SP1 to SP3 are mixed.

Hereinafter, for convenience of description, a case where the first subpixel SP1 emits red (R) light, the second subpixel SP2 emits green (G) light, and the third subpixel SP3 emits blue (B) light will be described for example.

The non-active area NA may be disposed in an edge region surrounding the active area AA which displays an image. At least one panel driving circuit for driving the plurality of subpixels SP may be disposed in the non-active area NA.

The timing controller 11 may receive digital video data D-DATA, transferred from a host system (not shown) to supply digital image data D-DATA to the data driver 12.

The timing controller 11 may receive a timing signal such as a vertical synchronization signal, a horizontal synchronization signal, a data enable signal, and a dot clock from an external device such as the host system to generate timing control signals for controlling an operation timing of the panel driving circuit.

The timing control signals may include a gate timing control signal GDC for controlling an operation timing of the gate driver 13, a data timing control signal DDC for controlling an operation timing of the data driver 12, and a power timing control signal PDC for controlling an operation timing of the power supply 20.

The data driver 12 may be connected to the plurality of subpixels SP through data lines DL (DL1 to DLm). The data driver 12 may generate data voltages Vdata, which are analog signals needed for driving of the plurality of subpixels SP, and may respectively supply the data voltages Vdata to the data lines DL.

The data driver 12 may sample and latch the digital image data D-DATA input from the timing controller 11 to generate parallel data, based on the data timing control signal DDC, and a digital-to-analog converter (DAC) may convert the digital image data D-DATA into analog data voltages Vdata, based on gamma compensation voltages, and may respectively supply the analog data voltages Vdata to the plurality of subpixels SP through the data lines DL. The analog data voltages Vdata may be analog voltage values of different voltage levels to correspond to image gray levels which are to be expressed in the plurality of subpixels SP.

The data driver 12 may output the data voltages Vdata to the plurality of subpixels SP through data lines DL (DL1 to DLm), based on the data timing control signal DDC. The data driver 12 may include a plurality of source driver integrated circuits (ICs) which may be disposed on one side of the display panel 10. Each of the source driver ICs may include a shift register, a latch, a level shifter, the DAC, and an output buffer. For example, the data driver 12 can be mounted on the upper surface of the display panel 10 in the form of a source driver integrated circuit (IC), but is not limited thereto.

The gate driver 13 may generate scan signals SC to supply the scan signals SC to the plurality of subpixels SP through gate lines GL (GL1 to GLn), based on the gate timing control signal GDC, and depending on the case, the gate driver 13 may generate emission control signals EM1 and EM2 to supply the emission control signals EM1 and EM2 to the plurality of subpixels SP, based on the gate timing control signal GDC.

The power supply 20 may be configured to supply voltages necessary for driving the plurality of subpixels SP. The power supply 20 may process an input power from a power source to generate a level-fixed high-level driving voltage (for example, EVDD of FIG. 2) and may supply the high-level driving voltage EVDD to the plurality of subpixels SP through power lines VDD1 to VDD3, based on the power timing control signal PDC.

Moreover, the power supply 20 may process the input power to generate a low-level voltage (for example, EVSS of FIG. 2) fixed to a level which is lower than that of the high-level driving voltage EVDD and may supply the low-level voltage EVSS to the plurality of subpixels SP, based on the power timing control signal PDC. The high-level driving voltage EVDD and the low-level voltage EVSS may each be used as a voltage for allow a light emitting device to emit light. The power supply 20 may include one or more circuits to process and supply voltages. In an example, the power supply 20 is configured to be connected to the power source.

Furthermore, the power supply 20 included in the display apparatus according to the present disclosure may supply high-level driving voltages of different levels to the first to third subpixels SP1 to SP3 emitting lights of different colors through the first to third power lines VDD1 to VDD3 electrically disconnected from one another.

To this end, the first to third subpixels SP1 to SP3 included in each unit pixel of the display panel 10 may be connected to the first to third power lines VDD1 to VDD3. In detail, in each unit pixel UP1 to UP4, the first subpixel SP1 may be connected to the first power line VDD1, the second subpixel SP2 may be connected to the second power line VDD2, and the third subpixel SP3 may be connected to the third power line VDD3.

Each of the first to third power lines VDD1 to VDD3 may include a mesh structure line, and the mesh structure lines of the first to third power lines VDD1 to VDD3 may be electrically disconnected from one another so as to supply high-level driving voltages of different levels to the first to third subpixels SP1 to SP3 emitting lights of different colors.

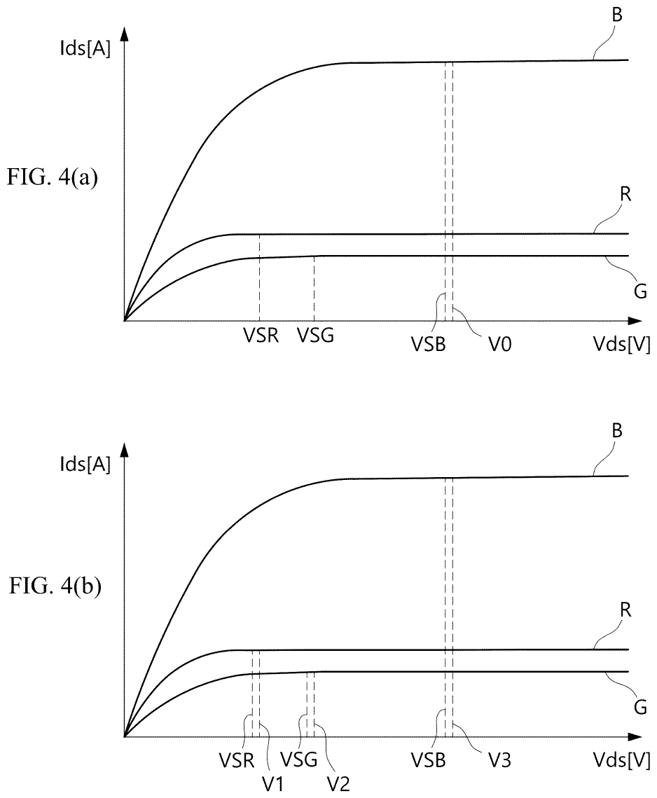

The power supply 20 may respectively supply first to third driving voltages (for example, V1 to V3 of FIG. 4(b)) of different levels to the first to third subpixels SP1 to SP3 through the first to third power lines VDD1 to VDD3, based on a saturation voltage of a driving transistor DT included in a corresponding one of the first to third subpixels SP1 to SP3.

For example, the power supply 20 may supply a first driving voltage through the first power line VDD1, supply a second driving voltage, having a level differing from a level of the first driving voltage, through the second power line VDD2 and supply a third driving voltage, having a level differing from a level of each of the first and second driving voltages, through the third power line VDD3, but is not limited thereto.

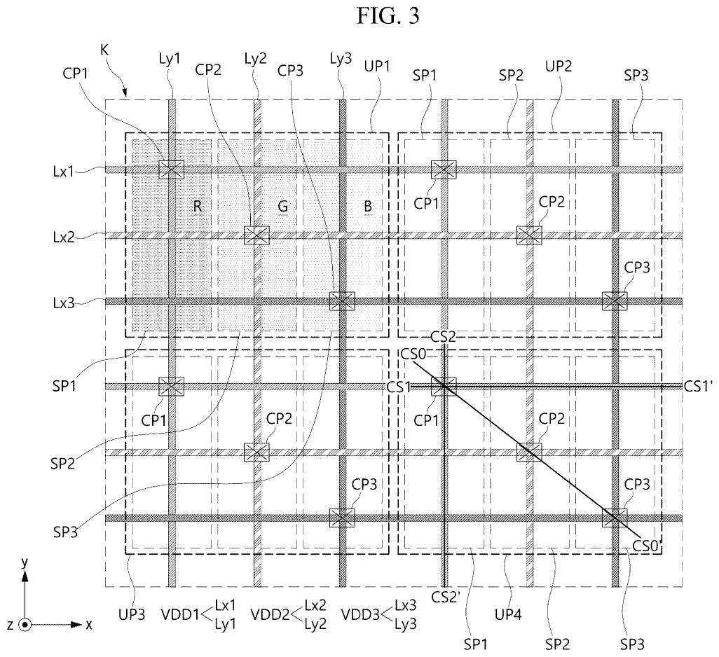

Therefore, the present disclosure may prevent or mitigate a degradation in the driving transistor DT included in each of the first to third subpixels SP1 to SP3 and may decrease the power consumption of the display apparatus. This will be described below in more detail with reference to FIG. 3.

As illustrated in FIG. 2, at least one of the plurality of subpixels SP may include, for example, a first switching transistor ST1, a second switching transistor ST2, a third switching transistor ST3, the driving transistor DT, a capacitor Cst, and a light emitting device OLED, but is not limited thereto.

A first electrode of the first switching transistor ST1 may be connected to the power lines VDD1 to VDD3 and may be supplied with the high-level driving voltage EVDD, a second electrode of the first switching transistor ST1 may be connected to the driving transistor DT, and a first emission control signal EM1 may be applied to a gate electrode of the first switching transistor ST1.

The first switching transistor ST1 may transfer the high-level driving voltage EVDD, applied to the first electrode thereof, to the driving transistor DT according to the first emission control signal EM1 applied to the gate electrode thereof. The first switching transistor ST1 may control the on/off of the high-level driving voltage EVDD applied to a subpixel in response to the first emission control signal EM1.

The power lines VDD1 to VDD3 of the first electrode of the first switching transistor ST1 may be connected to different power lines, based on a color of light emitted from a subpixel SP.

For example, in a case where the pixel equivalent circuit of FIG. 2 represents the first subpixel SP1 emitting red (R) light, the first electrode of the first switching transistor ST1 may be connected to the first power line VDD1 and may receive a first driving voltage V1 of a first level as the high-level driving voltage EVDD.

Alternatively, in a case where the pixel equivalent circuit of FIG. 2 represents the second subpixel SP2 emitting green (G) light, the first electrode of the first switching transistor ST1 may be connected to the second power line VDD2 and may receive a second driving voltage V2 of a second level as the high-level driving voltage EVDD.

In a case where the pixel equivalent circuit of FIG. 2 represents the third subpixel SP3 emitting blue (B) light, the first electrode of the first switching transistor ST1 may be connected to the third power line VDD3 and may receive a third driving voltage V3 of a third level as the high-level driving voltage EVDD.

A first electrode (for example, a drain electrode) of the driving transistor DT may be supplied with the high-level driving voltage EVDD from the first switching transistor ST1, and a second electrode (for example, a source electrode) thereof may be electrically connected to a first electrode (for example, an anode electrode) of the light emitting device OLED through the second switching transistor ST2, and the gate electrode of the driving transistor DT may be supplied with a voltage applied from a first node N1. The driving transistor DT may control the amount of driving current Ids flowing in the light emitting device OLED, based on a voltage applied from a first node N1 to a gate electrode thereof.

The second switching transistor ST2 may be disposed between the driving transistor DT and the light emitting device OLED, a first electrode of the second switching transistor ST2 may be connected to the driving transistor DT, and a second electrode of the second switching transistor ST2 may be electrically connected to the light emitting device OLED, and the gate electrode of the second switching transistor ST2 may be supplied with a second emission control signal EM2. In response to a second emission control signal EM2 applied to the gate electrode of the driving transistor DT, the second switching transistor ST2 may control the on/off of the driving current Ids applied from the driving transistor DT.

A first electrode (for example, a drain electrode) of the third switching transistor ST3 may be connected to a data line DL and may be supplied with a data voltage Vdata, a second electrode (for example, a source electrode) thereof may be electrically connected to the first node N1, and a gate electrode of the third switching transistor ST3 may be electrically connected to a gate line GL and may be supplied with a scan signal SC. The third switching transistor ST3 may transfer the data voltage Vdata, supplied through the data line DL, to the first node N1 in response to the scan signal SC supplied through the gate line GL.

The capacitor Cst may be electrically connected between the first node N1 and the second electrode (for example, a source electrode) of the driving transistor DT. The capacitor Cst may be electrically connected to the first node N1 and may be charged with a voltage applied to the first node N1.

In one or more aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

The light emitting device OLED may output light corresponding to the driving current Ids. The light emitting device OLED may emit light corresponding to one color among red (R), green (G), blue (B), and white.

The light emitting device OLED may include the anode electrode, an emission layer disposed on the anode electrode, and a cathode electrode supplying a common voltage.

For example, the emission layer may include one or more of a hole injection layer (HIL), a hole transmitting layer (HTL), an electron transmitting layer (ETL) and an electron injection layer (EIL), but the present disclosure is not limited thereto.

The emission layer may be implemented to emit light of the same color for each pixel, like white light, or may be implemented to emit lights of different colors for each subpixel SP, like red (R) light, green (G) light, or blue (B) light. A low-level voltage EVSS may be supplied to the cathode electrode. For example, the low-level voltage EVSS having the same level may be supplied to cathode electrodes of the first to third subpixels SP1 to SP3.

The light emitting device OLED may be a diode of a top emission type, or may be a diode of a bottom emission type.

Moreover, although not shown in FIG. 2, a compensation circuit (not shown) for compensating for a threshold voltage of the driving transistor DT may be further included in the subpixel SP. The compensation circuit may include at least one transistor connected to the driving transistor DT and may be provided in the subpixel SP.

The compensation circuit may be configured in a 3T1C structure where three transistors and one capacitor Cst are included in the subpixel SP, or may be configured in a 4T2C structure where four transistors and two capacitors Cst are included in the subpixel SP, or may be configured in various structures such as 5T2C, 6T1C, 6T2C, 7T1C, and 7T2C.

Moreover, in FIG. 2, a case where the driving transistor DT is electrically connected to the light emitting device OLED through the second switching transistor ST2 is illustrated for example, but the present disclosure is not limited thereto. For example, unlike FIG. 2, depending on the case, the second switching transistor ST2 may be omitted, and the driving transistor DT may be electrically connected to the light emitting device OLED without passing through another transistor.

Moreover, in FIG. 2, a case where the first switching transistor ST1 is provided is illustrated for example, but the present disclosure is not limited thereto. For example, depending on the case, the first switching transistor ST1 may be omitted in FIG. 2. For example, the driving transistor DT may be electrically connected to power supply 20 generating the high-level driving voltage EVDD without passing through another transistor.

Furthermore, the first to third power lines VDD1 to VDD3 described above with reference to FIGS. 1 and 2 may respectively include mesh structure lines electrically disconnected from one another, so as to stably supply the high-level driving voltage EVDD.

FIG. 3 is a diagram for illustrating a connection structure of first, second, and third power lines which are electrically disconnected from one another and have a mesh structure line, according to an example embodiment of the present disclosure.

FIG. 3 is an enlarged plan view of a region K of FIG. 1. As illustrated in FIG. 3, the display panel 10 may include a plurality of unit pixels including first to fourth unit pixels UP1 to UP4.

As illustrated in FIG. 3, the first to fourth unit pixels UP1 to UP4 may each include first to third subpixels SP1 to SP3. Hereinafter, an example will be described where each of the second to fourth unit pixels UP2 to UP4 includes the first to third subpixels SP1 to SP3 which are arranged to be same as or similar to the first unit pixel UP1.

As one example, each of the first subpixel SP1 to the third subpixel SP3 may include a light emitting device OLED emitting red (R) light, green (G) light or blue (B) light. In FIG. 3, for example, the first subpixel SP1 may include a light emitting device OLED emitting red (R) light, the second subpixel SP2 may include a light emitting device OLED emitting green (G) light, and the third subpixel SP3 may include a light emitting device OLED emitting blue (B) light, but is not limited thereto.

The power supply 20 may respectively supply, as the high-level driving voltage EVDD, first to third driving voltages (for example, V1 to V3 of FIG. 4(b)) of different levels through the first to third power lines VDD1 to VDD3 to the first to third subpixels SP1 to SP3 included in each of the first to fourth unit pixels UP1 to UP4 of FIG. 3.

For example, the power supply 20 may supply the first driving voltage V1 of a first level through the first power line VDD1 to the first subpixel SP1 of each of the first to fourth unit pixels UP1 to UP4, may supply the second driving voltage V2 of a second level through the second power line VDD2 to the second subpixel SP2 of each of the first to fourth unit pixels UP1 to UP4, and may supply the third driving voltage V3 of a third level through the third power line VDD3 to the third subpixel SP3 of each of the first to fourth unit pixels UP1 to UP4.

Here, a voltage level of each of the first to third driving voltages V1 to V3 may be determined based on a saturation voltage of the driving transistor DT included in a respective one of the first to third subpixels SP1 to SP3. This will be described below with reference to FIG. 4(b). For example, the power supply 20 may supply first to third driving voltages V1 to V3 of different levels to the first to third subpixels SP1 to SP3, respectively, through the first to third power lines VDD1 to VDD3.

The first to third power lines VDD1 to VDD3, as in FIG. 3, may respectively include mesh structure lines electrically disconnected from one another.

The mesh structure line of the first power line VDD1 may include a plurality of first horizontal lines Lx1 and a plurality of first vertical lines Ly1, which are connected to the first subpixel SP1. The mesh structure line of the second power line VDD2 may include a plurality of second horizontal lines Lx2 and a plurality of second vertical lines Ly2, which are connected to the second subpixel SP2. The mesh structure line of the third power line VDD3 may include a plurality of third horizontal lines Lx3 and a plurality of third vertical lines Ly3, which are connected to the third subpixel SP3.

Here, the first to third horizontal lines Lx1 to Lx3 may be parallel to a horizontal direction x of the display panel 10, and the first to third vertical lines Ly1 to Ly3 may be parallel to a vertical direction y of the display panel 10. Accordingly, in each of the first to fourth unit pixels UP1 to UP4, the first to third horizontal lines Lx1 to Lx3 may intersect the first to third vertical lines Ly1 to Ly3. For example, each of the first to third horizontal lines Lx1 to Lx3 may intersect each of the first to third vertical lines Ly1 to Ly3.

In each of the first to fourth unit pixels UP1 to UP4, the first to third vertical lines Ly1 to Ly3 may be disposed on the same layer and may be spaced apart from one another in the horizontal direction x.

In each of the first to fourth unit pixels UP1 to UP4, the first to third horizontal lines Lx1 to Lx3 may be disposed on the same layer and may be spaced apart from one another in the vertical direction y.

In each of the first to fourth unit pixels UP1 to UP4, the plurality of first horizontal lines Lx1 and the plurality of first vertical lines Ly1 of the first power line VDD1 may be electrically connected to each other, the plurality of second horizontal lines Lx2 and the plurality of second vertical lines Ly2 of the second power line VDD2 may be electrically connected to each other, and the plurality of third horizontal lines Lx3 and the plurality of third vertical lines Ly3 of the third power line VDD3 may be electrically connected to each other.

For example, in the first to fourth unit pixels UP1 to UP4, in the first subpixels SP1, the plurality of first horizontal lines Lx1 and the plurality of first vertical lines Ly1 of the first power line VDD1 may be electrically connected to each other, in the second subpixels SP2, the plurality of second horizontal lines Lx2 and the plurality of second vertical lines Ly2 of the second power line VDD2 may be electrically connected to each other, in the third subpixels SP3, the plurality of third horizontal lines Lx3 and the plurality of third vertical lines Ly3 of the third power line VDD3 may be electrically connected to each other.

For example, in each of the first to fourth unit pixels UP1 to UP4, a first contact point CP1 at which the first horizontal line Lx1 and the first vertical line Ly1 are electrically connected to each other at an intersection point therebetween may be provided, a second contact point CP2 at which the second horizontal line Lx2 and the second vertical line Ly2 are electrically connected to each other at an intersection point therebetween may be provided, and a third contact point CP3 at which the third horizontal line Lx3 and the third vertical line Ly3 are electrically connected to each other at an intersection point therebetween may be provided.

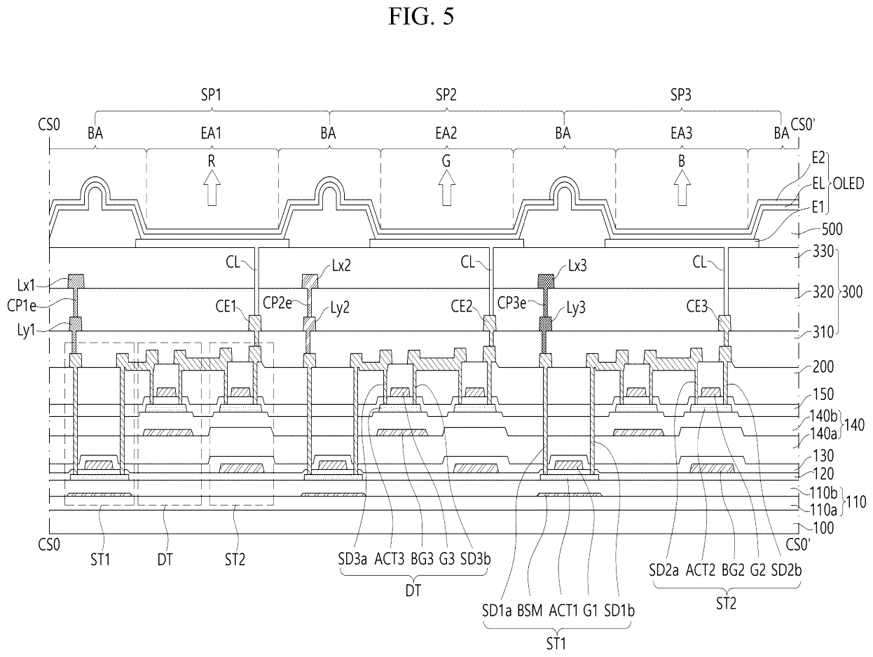

The first horizontal line Lx1 and the first vertical line Ly1 may be electrically connected to each other in a thickness direction z at the first contact point CP1, the second horizontal line Lx2 and the second vertical line Ly2 may be electrically connected to each other in the thickness direction z at the second contact point CP2, and the third horizontal line Lx3 and the third vertical line Ly3 may be electrically connected to each other in the thickness direction z at the third contact point CP3. This will be described below in detail with reference to FIGS. 5 to 7.

The first to third contact points CP1 to CP3 may be disposed one-by-one for each unit pixel, and positions of the first to third contact points CP1 to CP3 may be spaced apart from one another not to overlap each other. For example, the positions of the first to third contact points CP1 to CP3 may be spaced apart from one another not to overlap each other in the horizontal direction and the vertical direction, but is not limited thereto. For example, in each unit pixel, the first contact point CP1 may be disposed to overlap the first subpixel SP1, the second contact point CP2 may be disposed to overlap the second subpixel SP2, and the third contact point CP3 may be disposed to overlap the third subpixel SP3.

The plurality of first horizontal lines Lx1 may be insulated from the second and third vertical lines Ly2 and Ly3, the plurality of second horizontal lines Lx2 may be insulated from the first and third vertical lines Ly1 and Ly3, and the plurality of third horizontal lines Lx3 may be insulated from the first and second vertical lines Ly1 and Ly2.

For example, the plurality of first horizontal lines Lx1 may be insulated from the second and third vertical lines Ly2 and Ly3 in the thickness direction z, the plurality of second horizontal lines Lx2 may be insulated from the first and third vertical lines Ly1 and Ly3 in the thickness direction z, and the plurality of third horizontal lines Lx3 may be insulated from the first and second vertical lines Ly1 and Ly2 in the thickness direction z, but is not limited thereto.

For example, the first horizontal line Lx1 may be insulated from the second and third vertical lines Ly2 and Ly3 in the thickness direction z at a point intersecting the second and third vertical lines Ly2 and Ly3, the second horizontal line Lx2 may be insulated from the first and third vertical lines Ly1 and Ly3 in the thickness direction z at a point intersecting the first and third vertical lines Ly1 and Ly3, and the third horizontal line Lx3 may be insulated from the first and second vertical lines Ly1 and Ly2 in the thickness direction z at a point intersecting the first and second vertical lines Ly1 and Ly2. This will be described below in detail with reference to FIGS. 5 to 7.

As described above, each of the first to third power lines VDD1 to VDD3 according to an example embodiment of the present disclosure may include the mesh structure line, and the mesh structure lines of the first to third power lines VDD1 to VDD3 may be electrically disconnected from one another.

For instance, the mesh structure line of one (or each) of the first to third power lines VDD1 to VDD3 may be electrically disconnected from the mesh structure line of at least another one of the first to third power lines VDD1 to VDD3. For instance, the mesh structure line of one (or each) of the first to third power lines VDD1 to VDD3 may be electrically disconnected from the mesh structure lines of the others of the first to third power lines VDD1 to VDD3.

For instance, the mesh structure line of the first power line VDD1 may be electrically disconnected from the mesh structure line of the second power line VDD2 and from the mesh structure line of the third power line VDD3. The mesh structure line of the second power line VDD2 may be electrically disconnected from the mesh structure line of the first power line VDD1 and from the mesh structure line of the third power line VDD3. The mesh structure line of the third power line VDD3 may be electrically disconnected from the mesh structure line of the first power line VDD1 and from the mesh structure line of the second power line VDD2.

The power supply 20 according to an example embodiment of the present disclosure may supply, as the high-level driving voltage EVDD, the first to third driving voltages V1 to V3 of different levels through the first to third power lines VDD1 to VDD3 including the mesh structure lines electrically disconnected from one another.

Accordingly, the present disclosure may prevent or mitigate a degradation in the driving transistor DT included in each of the first to third subpixels SP1 to SP3 and may decrease the power consumption of the display apparatus.

FIGS. 4(a) and 4(b) are example diagrams for illustrating a saturation voltage of a driving transistor electrically connected to a light emitting device emitting red (R) light, green (G) light, or blue (B) light in each subpixel.

FIG. 4(a) illustrates a comparative example, and FIG. 4(b) illustrates an example embodiment of the present disclosure. In FIGS. 4(a) and 4(b), the x axis represents a drain-source voltage Vds of a driving transistor DT included in a subpixel emitting red (R) light, green (G) light, or blue (B) light, and the y axis represents a driving current Ids of the driving transistor DT.

In FIGS. 4(a) and 4(b), R, G, and B are characteristic graphs of Vds and Ids of each driving transistor DT electrically connected to a light emitting device OLED of light emitting devices OLED in the subpixel emitting red (R) light, green (G) light, or blue (B) light, and each of VSR, VSG, and VSB represents a saturation voltage of a driving transistor DT electrically connected to the respective light emitting device OLED emitting red (R) light, green (G) light, or blue (B) light.

Each of the saturation voltages VSR, VSG, and VSB of the driving transistors DT may vary based on a luminance and a color temperature of a color of light emitted from a respective light emitting device OLED connected to the driving transistor DT, a width and a length of the respective light emitting device OLED, and a target current value.

For example, the saturation voltage VSR of a driving transistor DT electrically connected to a red (R) light emitting device OLED may be the lowest, the saturation voltage VSB of a driving transistor DT electrically connected to a blue (B) light emitting device OLED may be the highest, and the saturation voltage VSG of a driving transistor DT electrically connected to a green (G) light emitting device OLED may have a value between the saturation voltages VSR and VSB.

As described above, under a condition where saturation voltages differ, in a case where the subpixels SP emitting lights of different colors are connected to one power line, as in FIG. 4(a), each subpixel SP may be supplied with the high-level driving voltage EVDD having the same voltage level V0 from the power supply. For example, the subpixels SP emitting lights of different colors may be supplied with the high-level driving voltage EVDD of a V0 voltage level which is higher than VSB with respect to the highest saturation voltage VSB, for a stable operation of the display apparatus.

In this case, the subpixels SP in each unit pixel may be supplied with the high-level driving voltage EVDD of a V0 voltage level which is set with respect to the highest saturation voltage VSB, and thus, the power consumption of the display apparatus may increase.

Furthermore, in a driving transistor DT electrically connected to the red (R) or green (G) light emitting device OLED, due to a difference between the high-level driving voltage EVDD of a V0 voltage level and each saturation voltage VSR or VSG, the driving transistor DT may be rapidly degraded, and due to this, a possibility that an operation error of the display apparatus occurs may increase.

However, in the example embodiments of the present disclosure, as described above with reference to FIGS. 1 to 3, in a state where the first to third power lines VDD1 to VDD3 electrically disconnected from one another are respectively connected to the first to third subpixels SP1 to SP3 emitting lights of different colors, as in FIG. 4(b), the power supply 20 may supply, as the high-level driving voltage EVDD, the first to third driving voltages V1 to V3 of different levels through the first to third power lines VDD1 to VDD3, and thus, the power consumption of the display apparatus may be reduced, and a degradation in the driving transistor DT included in each subpixel SP may be reduced.

For example, as in FIG. 4(b), the first driving voltage V1 may have a level which is lower than that of the second driving voltage V2, and the third driving voltage V3 may have a level which is higher than that of each of the first and second driving voltages V1 and V2.

The first to third driving voltages V1 to V3 may be set with respect to the saturation voltages VSR, VSG, and VSB of the driving transistors DT included in the first to third subpixels SP1 to SP3. In detail, the first driving voltage V1 may be set with respect to the saturation voltage VSR of the driving transistor DT of the first subpixel SP1, the second driving voltage V2 may be set with respect to the saturation voltage VSG of the driving transistor DT of the second subpixel SP2, and the third driving voltage V3 may be set with respect to the saturation voltage VSB of the driving transistor DT of the third subpixel SP3.

For example, the first driving voltage V1 may be set with respect to the saturation voltage VSR of the driving transistor DT of the first subpixel SP1 emitting red (R) light, the second driving voltage V2 may be set with respect to the saturation voltage VSG of the driving transistor DT of the second subpixel SP2 emitting green (G) light, and the third driving voltage V3 may be set with respect to the saturation voltage VSB of the driving transistor DT of the third subpixel SP3 emitting blue (B) light.

For example, as in FIG. 4(b), the first driving voltage V1 may be set to higher than or equal to the saturation voltage VSR of the first subpixel SP1 emitting red (R) light, and for example, may be lower than the saturation voltage VSG of the second subpixel SP2 emitting green (G) light. Also, the second driving voltage V2 may be set to higher than or equal to the saturation voltage VSG of the second subpixel SP2 emitting green (G) light, and for example, may be lower than the saturation voltage VSB of the third subpixel SP3 emitting blue (B) light. Also, the third driving voltage V3 may be set to higher than or equal to the saturation voltage VSB of the third subpixel SP3 emitting blue (B) light, and for example, may be higher than the saturation voltages VSR and VSG.

Accordingly, in one or more aspects of the present disclosure, the subject technology may decrease the power consumption of the display apparatus and may minimize or reduce a voltage level difference between a saturation voltage and a high-level driving voltage of the driving transistor DT included in each subpixel SP, thereby reducing a degradation in a driving transistor.

Moreover, as described above with reference to FIG. 3, in one or more aspects of the present disclosure, the first to third power lines VDD1 to VDD3 may have mesh structure lines electrically disconnected from one another. Accordingly, even when a portion of each of the first to third power lines VDD1 to VDD3 is open-circuited by a foreign material, a driving voltage may not be cut off and may be supplied to subpixels emitting lights of the same color through a bypass path, and thus, the driving stability of the display apparatus may be maintained.

Hereinafter, a detailed interlayer structure of each of the first to third power lines VDD1 to VDD3 illustrated in FIG. 3 will be described, and for example, a cross-sectional structure of a display apparatus may be described.

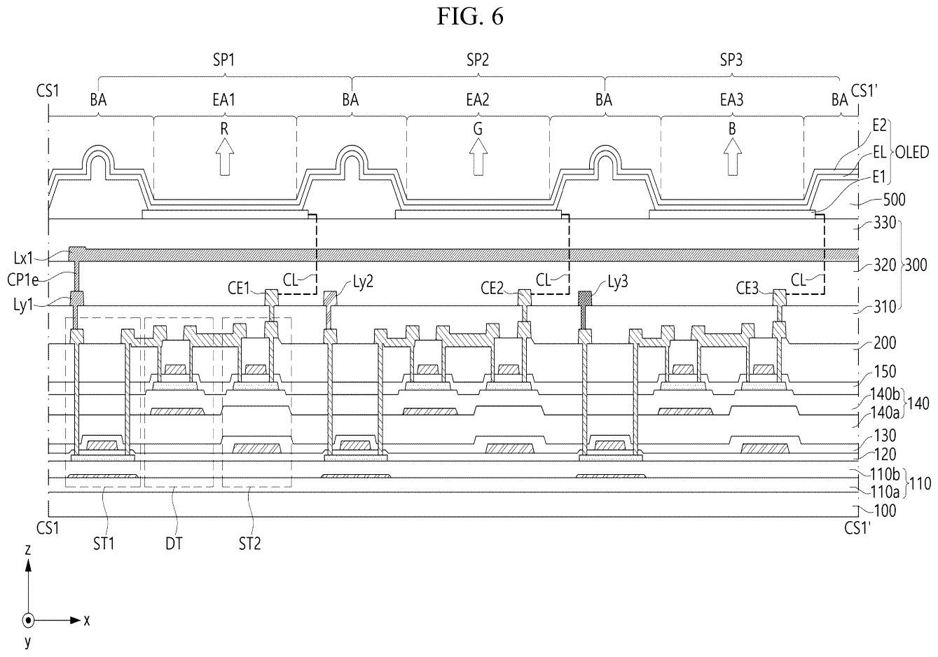

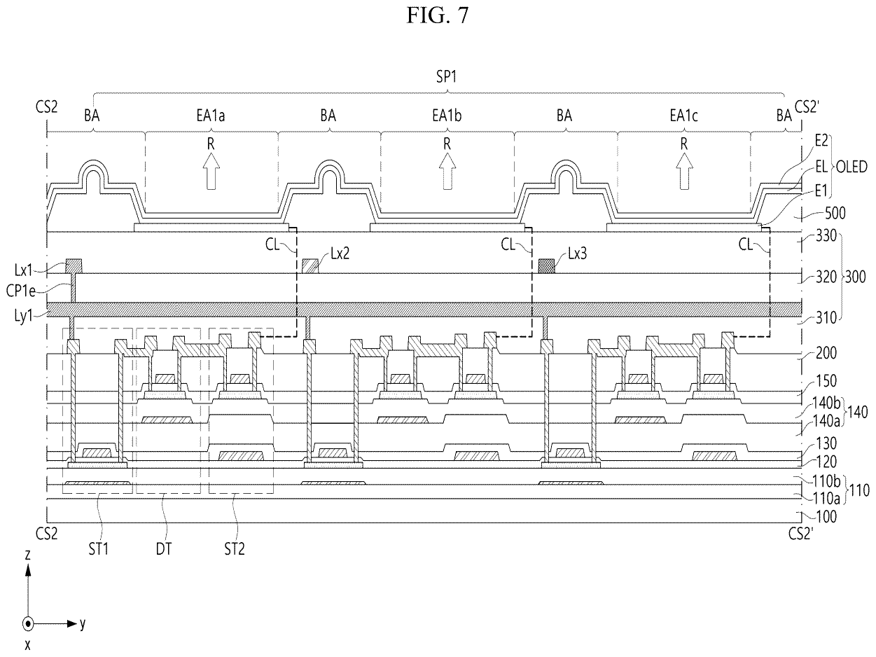

FIG. 5 is a diagram for illustrating an example embodiment of a cross-sectional surface of a display apparatus taken along line CS0-CS0′ in a diagonal direction with respect to a horizontal direction x and a vertical direction y in FIG. 3. FIG. 6 is a diagram for illustrating an example embodiment of a cross-sectional surface of a display apparatus taken along line CS1-CS1′ parallel to the horizontal direction x in FIG. 3. FIG. 7 is a diagram for illustrating an example embodiment of a cross-sectional surface of a display apparatus taken along line CS2-CS2′ parallel to the vertical direction y in FIG. 3.

FIGS. 5 to 7 illustrate example cross-sectional surfaces of a display apparatus provided in a fourth unit pixel UP4 in FIG. 3, and the cross-sectional surfaces illustrated in FIGS. 5 to 7 may be identically applied to the first to third unit pixels UP1 to UP3 in FIG. 3.

A plurality of transistors ST1, DT, and ST2 illustrated in FIGS. 5 to 7, for example, are illustrated as a transistor disposed in a path up to a light emitting device OLED from a power line VDD1 or VDD2 or VDD3 in the pixel equivalent circuit illustrated in FIG. 2.

Therefore, the present disclosure is not limited to a connection structure of the plurality of transistors ST1, DT, and ST2 illustrated in FIGS. 5 to 7, and the connection structure of the plurality of transistors ST1, DT, and ST2 illustrated in FIGS. 5 to 7 may be variously modified. Hereinafter, the connection structure of the plurality of transistors illustrated in FIGS. 5 to 7 will be described for example.

Moreover, in FIGS. 5 to 7, a case where a first subpixel SP1 emits light of the first color such as red (R) light, a second subpixel SP2 emits light of the second color such as green (G) light, and a third subpixel SP3 emits light of the third color such as blue (B) light may be described for example.

The display apparatus according to an example embodiment of the present disclosure, as illustrated in FIGS. 5 to 7, may include a substrate 100, a first buffer layer 110, a first gate insulation layer 120, a first interlayer insulation layer 130, a second buffer layer 140, a second gate insulation layer 150, a second interlayer insulation layer 200, a planarization layer 300, a bank 500, a light emitting device OLED, a first switching transistor ST1, a second switching transistor ST2, a driving transistor DT, a first power line VDD1, a second power line VDD2, and a third power line VDD3, but is not limited thereto. More or less elements may be included.

In FIGS. 5 to 7, at least one of the first and second switching transistors ST1 and ST2 may be omitted. Hereinafter, however, as illustrated in FIGS. 5 to 7, a case where the first and second switching transistors ST1 and ST2 are provided will be described for example.

The substrate 100 may include a plastic material having flexibility and may have a flexible characteristic, and moreover, may include a glass material of a thin thickness having flexibility. The substrate 100 may be disposed in an active area AA and a non-active area NA of a display panel 10.

For example, the substrate 100 may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS), which is only an example and is not necessarily limited thereto.

The substrate 100 may have a multi-layer structure including an insulating material. For example, the substrate 100 may include an insulating material and a polymer material such as polyimide (PI).

The first buffer layer 110 may be disposed in the active area AA and the non-active area NA of the substrate 100. The first buffer layer 110 may protect structures on the substrate 100 vulnerable to the penetration of external water and may planarize a surface of the substrate 100.

The first buffer layer 110 may include an insulating material, and for example, may include an inorganic insulating material such as silicon oxide (SiOx) and silicon nitride (SiNx) and may include a multi-layer structure including the same material or different materials.

For example, the first buffer layer 110 may be formed by inorganic film in a single layer or in multiple layers, for example, the inorganic film in a single layer may be a silicon oxide (SiO) film or a silicon nitride (SiN) film, and inorganic films in multiple layers may formed by alternately stacking one or more silicon oxide (SiO) films, one or more silicon nitride (SiN) films, and one or more amorphous silicon (a-Si), but the present disclosure is not limited thereto.

For example, the first buffer layer 110 may include a multi buffer layer 110a and an active buffer layer 110b, which include different insulating materials and are stacked. A first metal layer BSM of the first switching transistor ST1 may be disposed between the multi buffer layer 110a and the active buffer layer 110b. A first active layer ACT1 of the first switching transistor ST1 may be disposed on the active buffer layer 110b.

The first gate insulation layer 120 may cover the first active layer ACT1 of the first switching transistor ST1 and may be disposed on the first buffer layer 110. The first gate insulation layer 120 may insulate a first gate electrode G1 of the first switching transistor ST1 from the first active layer ACT1. The first gate insulation layer 120 may include at least one of SiOx, SiNx, and silicon oxynitride (SiOxNy). The first gate electrode G1 of the first switching transistor ST1 may be disposed on the first gate insulation layer 120, and a second metal layer BG2 of the second switching transistor ST2 may be disposed on the first gate insulation layer 120.

The first interlayer insulation layer 130 may be disposed on the first gate insulation layer 120 to cover the first gate electrode G1 and the second metal layer BG2. The first interlayer insulation layer 130 may fully cover the active area AA of the substrate 100 and may include an insulating material.

The first interlayer insulation layer 130 may include one or more inorganic layers of SiOx, SiNx, and SiOxNy.

The second buffer layer 140 may be disposed on the first interlayer insulation layer 130. The second buffer layer 140 may include an insulating material. For example, the second buffer layer 140 may include an inorganic insulating material such as SiOx or SiNx.

The second buffer layer 140 may have a multi-layer structure. For example, the second buffer layer 140 may include a nitride buffer layer 140a and an oxide buffer layer 140b, which include different materials, but is not limited thereto. For example, the nitride buffer layer 140a may be disposed on the first interlayer insulation layer 130, and the oxide buffer layer 140b may be disposed on the nitride buffer layer 140a. The nitride buffer layer 140a may include SiNx, and the oxide buffer layer 140b may include SiOx. A hydrogen concentration of the nitride buffer layer 140a may be higher than a hydrogen concentration of the oxide buffer layer 140b.

A third metal layer BG3 of the driving transistor DT may be disposed between the nitride buffer layer 140a and the oxide buffer layer 140b. For example, the oxide buffer layer 140b may be disposed to cover the third metal layer BG3 of the driving transistor DT and the nitride buffer layer 140a.

A second active layer ACT2 of the second switching transistor ST2 and a third active layer ACT3 of the driving transistor DT may be disposed on the oxide buffer layer 140b.

The second gate insulation layer 150 may be disposed on the second buffer layer 140 to cover the second active layer ACT2, and a second gate electrode G2 of the second switching transistor ST2 and a third gate electrode G3 of the driving transistor DT may be disposed on the second gate insulation layer 150.

The second gate insulation layer 150 may insulate the second gate electrode G2 of the second switching transistor ST2 from the second active layer ACT2 and may insulate the third gate electrode G3 of the driving transistor DT from the third active layer ACT3.

The second gate insulation layer 150 may include at least one of SiOx, SiNx, and SiOxNy. For example, SiOx may include silicon dioxide (SiO₂).

The second interlayer insulation layer 200 may be disposed on the second gate insulation layer 150 to cover the second gate electrode G2 of the second switching transistor ST2 and the third gate electrode G3 of the driving transistor DT. The second interlayer insulation layer 200 may include an insulating material such as SiOx, SiNx, or SiOxNy.

A first source electrode SD1a and a first drain electrode SD1b of the first switching transistor ST1, a second source electrode SD2a and a second drain electrode SD2b of the second switching transistor ST2, and a third source electrode SD3a and a third drain electrode SD3b of the driving transistor DT may be disposed on the second interlayer insulation layer 200.

The first source electrode SD1a and the first drain electrode SD1b of the first switching transistor ST1 may pass through the first gate insulation layer 120, the first interlayer insulation layer 130, the second buffer layer 140, the second gate insulation layer 150, and the second interlayer insulation layer 200 and may contact the first active layer ACT1.

Each of the second source electrode SD2a and the second drain electrode SD2b of the second switching transistor ST2 and the third source electrode SD3a and the third drain electrode SD3b of the driving transistor DT may pass through the second gate insulation layer 150 and the second interlayer insulation layer 200 and may contact the second active layer ACT2 and the third active layer ACT3.

For example, the second source electrode SD2a and the second drain electrode SD2b of the second switching transistor ST2 may be disposed on the second interlayer insulation layer 200, the second source electrode SD2a and the second drain electrode SD2b may pass through the second gate insulation layer 150 and the second interlayer insulation layer 200 and may contact the second active layer ACT2.

For example, the third source electrode SD3a and the third drain electrode SD3b of the driving transistor DT may be disposed on the second interlayer insulation layer 200, the third source electrode SD3a and the third drain electrode SD3b may pass through the second gate insulation layer 150 and the second interlayer insulation layer 200 and may contact the third active layer ACT3.

The planarization layer 300 may include an insulating material and may be disposed on the second interlayer insulation layer 200 to cover the first source electrode SD1a and the first drain electrode SD1b of the first switching transistor ST1, the second source electrode SD2a and the second drain electrode SD2b of the second switching transistor ST2, and the third source electrode SD3a and the third drain electrode SD3b of the driving transistor DT.

The planarization layer 300 may remove a step height which occurs due to the plurality of transistors ST1, ST2, and DT disposed in each subpixel SP1 to SP3. An upper surface of the planarization layer 300 may include a flat surface and may include a material having high flowability. For example, the planarization layer 300 may include an organic insulating material.

The planarization layer 300 may include a multi-layer structure where a plurality of layers are stacked, and for example, the planarization layer 300 may include a first planarization layer 310, a second planarization layer 320, and a third planarization layer 330, which are sequentially stacked, but is not limited thereto. More or less layers may be included.

The planarization layer 300 may be formed of one or more materials of acrylic resin, epoxy resin, phenolic resin, polyamides resin, unsaturated polyesters resin, polyphenylene resin, polyphenylene sulfides resin, and benzocyclobutene, but embodiments are not limited thereto.

The first planarization layer 310 may remove a step height caused by a driving circuit such as the first and second switching transistors ST1 and ST2 and the driving transistor DT. An upper surface of each of the first planarization layer 310, the second planarization layer 320, and the third planarization layer 330 may include a flat surface.

To this end, the first to third planarization layers 310 to 330 may include a material having high flowability. For example, the first to third planarization layers 310 to 330 may include an organic insulating material, and the first to third planarization layers 310 to 330 may include the same material or different materials.

For example, the first planarization layer 310 may be disposed on the second interlayer insulation layer 200, the second planarization layer 320 may be disposed on the first planarization layer 310, and the third planarization layer 330 may be disposed on the second planarization layer 320.

The first vertical line Ly1 of the first power line VDD1, the second vertical line Ly2 of the second power line VDD2, the third vertical line Ly3 of the third power line VDD3, and first to third center electrodes CE1 to CE3 may be disposed between the first planarization layer 310 and the second planarization layer 320.

The first to third vertical lines Ly1 to Ly3 and the first to third center electrodes CE1 to CE3 may include a conductive material, and for example, may include metal such as aluminum (Al), chrome (Cr), copper (Cu), titanium (Ti), molybdenum (Mo), and tungsten (W). The first to third vertical lines Ly1 to Ly3 and the first to third center electrodes CE1 to CE3 may include the same conductive material.

In each of the first to third subpixels SP1 to SP3, a respective one of the first to third center electrodes CE1 to CE3 may be connected to the second drain electrode SD2b of the second switching transistor ST2 through the first planarization layer 310, and moreover, may be connected to a first electrode E1 (for example, an anode electrode) of the respective light emitting device OLED through a line CL passing through the second and third planarization layers 320 and 330.

The first to third vertical lines Ly1 to Ly3 may be spaced apart from one another in the horizontal direction x and may extend in a direction parallel to the vertical direction y. In each of the first to third subpixels SP1 to SP3, a respective one of the first to third vertical lines Ly1 to Ly3 may be electrically connected to the first source electrode SD1a of the respective first switching transistor ST1 through the first planarization layer 310.

The first horizontal line Lx1 of the first power line VDD1, the second horizontal line Lx2 of the second power line VDD2, and the third horizontal line Lx3 of the third power line VDD3 may be disposed between the second planarization layer 320 and the third planarization layer 330.

The first to third horizontal lines Lx1 to Lx3 may be spaced apart from one another in the vertical direction y and may extend in a direction parallel to the horizontal direction x. In the first to third subpixels SP1 to SP3, the first to third horizontal lines Lx1 to Lx3 may be electrically connected to the first to third vertical lines Ly1 to Ly3, respectively, through the second planarization layer 320.

For example, the first horizontal line Lx1 and the first vertical line Ly1 may be electrically connected to each other, the second horizontal line Lx2 and the second vertical line Ly2 may be electrically connected to each other, and the third horizontal line Lx3 and the third vertical line Ly3 may be electrically connected to each other.

The first to third vertical lines Ly1 to Ly3 may include a conductive material, and for example, may include metal such as Al, Cr, Cu, Ti, Mo, and W.

The first to third vertical lines Ly1 to Ly3 may include the same conductive material, or the first to third vertical lines Ly1 to Ly3 may include different conductive materials.

The bank 500 may be disposed on the third planarization layer 330 and may define emission regions EA1 to EA3 of the first to third subpixels SP1 to SP3, respectively. A bank region BA overlapping the bank 500 may be disposed between the emission regions EA1 to EA3.

For example, as illustrated in FIG. 5, a first emission region EA1 of the first subpixel SP1, a second emission region EA2 of the second subpixel SP2, and a third emission region EA3 of the third subpixel SP3 may be defined by the bank 500. For example, the first to third emission regions EA1 to EA3 may be divided by the bank 500.

In FIG. 7, a case where one subpixel (for example, SP1) includes a plurality of emission regions EA1a, EA1b, and EA1c divided by the bank 500 is illustrated for example, but this may be merely an example embodiment and the present disclosure is not limited thereto. For example, unlike FIG. 7, the first subpixel SP1 may include one emission region which is not divided by the bank 500.

The bank 500 may include an insulating material, and for example, may include an organic insulating material. The bank 500 may include a material which differs from that of the planarization layer 300. The bank 500 may cover an edge of the first electrode E1 included in the light emitting device OLED. An emission layer EL and a second electrode E2 of the light emitting device OLED may be stacked on a partial region of the first electrode E1 exposed by the bank 500.

As an example, the bank 500 may include an organic insulating material such as acryl resin, epoxy resin, phenolic resin, polyamide resin, and/or polyimide resin, etc. Alternatively, the bank 500 may include an inorganic insulating material such as silicon nitride, aluminum nitride, zirconium nitride, titanium nitride, hafnium nitride, tantalum nitride, silicon oxide, aluminum oxide, or titanium oxide, etc. Also, the bank 500 may include a black dye in order to absorb light incident from the outside (e.g., outside of the display apparatus).

Light emitting devices OLED emitting lights of different colors may be respectively disposed in the first to third emission regions EA1 to EA3, and each of the light emitting devices OLED may include the first electrode E1, the emission layer EL, and the second electrode E2.

The first electrode E1, for example, may function as an anode electrode and may include a conductive material. The first electrode E1 may have a high reflectance. For example, the first electrode E1 may include metal such as Al and silver (Ag). The first electrode E1 may have a multi-layer structure. For example, the first electrode E1 may have a structure where a reflective electrode including metal is disposed between transparent electrodes including a transparent conductive material such as indium tin oxide (ITO) or indium zinc oxide (IZO).

The emission layer EL may generate light of luminance corresponding to a voltage difference between the first electrode E1 and the second electrode E2. For example, the emission layer EL may include an emission material layer (EML) including an emission material. The emission material may include an organic material, an inorganic material, or a hybrid material. For example, the emission layer EL may include an emission material layer including an organic material.

The emission layer EL may include at least one of a first emission common layer (not shown) disposed between first electrodes E1 and a second emission common layer (not shown) disposed between second electrodes E2. Each of the first emission common layer (not shown) and the second emission common layer (not shown) may include at least one of a hole injection layer (HIL), a hole transport layer (HTL), an electron transport layer (ETL), and an electron injection layer (EIL).

The emission layer EL may emit light having one color of red (R), green (G), and blue (B). For example, as illustrated in FIG. 5, an emission layer disposed in the first subpixel SP1 may emit red (R) light, an emission layer disposed in the second subpixel SP2 may emit green (G) light, and an emission layer disposed in the third subpixel SP3 may emit blue (B) light.

The second electrode E2, for example, may function as a cathode electrode and may include a conductive material. The second electrode E2 may include a material which differs from that of the first electrode E1. For example, the second electrode E2 may be a transparent electrode including a transparent conductive material such as ITO or IZO. The second electrode E2 may have a transmittance which is higher than that of the first electrode E1. Accordingly, in the display apparatus according to an example embodiment of the present disclosure, light generated by the emission layer EL may be emitted through the second electrode E2.

For example, each of the first electrode E1 and the second electrode E2 may comprise a metal material such as Au, W, Pt, Si, Ir, Ag, Cu, Ni, Ti, or Cr, and an alloy thereof. Alternatively, each of the first electrode E1 and the second electrode E2 may include a transparent conductive material such as ITO indium tin oxide or IZO indium zinc oxide, but is not limited thereto.

The first switching transistor ST1 may include the first metal layer BSM, the first gate electrode G1, the first active layer ACT1, the first source electrode SD1a, and the first drain electrode SD1b, and the first active layer ACT1 may include, for example, a semiconductor formed of low temperature poly silicon (LTPS). The first metal layer BSM may perform a light blocking function of blocking external light flowing into the first active layer ACT1. Although not shown, depending on the case, the first metal layer BSM may be electrically connected to one of the first gate electrode G1, a first source electrode, the first drain electrode SD1b, and a constant voltage source.

The second switching transistor ST2 may include the second metal layer BG2, the second gate electrode G2, the second active layer ACT2, the second source electrode SD2a, and the second drain electrode SD2b, and the second active layer ACT2 may include, for example, an oxide semiconductor. The second metal layer BG2 may block external light flowing into the second active layer ACT2. Although not shown, depending on the case, the second metal layer BG2 may be electrically connected to the first gate electrode G1 and may function as a bottom gate electrode.

The driving transistor DT may include the third metal layer BG3, the third gate electrode G3, the third active layer ACT3, the third source electrode SD3a, and the third drain electrode SD3b, and the third active layer ACT3 may include, for example, an oxide semiconductor. The third metal layer BG3 may block external light flowing into the third active layer ACT3. Although not shown, depending on the case, the third metal layer BG3 may be electrically connected to one of the third source electrode SD3a and the third drain electrode SD3b.

According to an example embodiment of the present disclosure, as described above with reference to FIG. 3, the first power line VDD1 may include a plurality of first horizontal lines Lx1 and a plurality of first vertical lines Ly1, the second power line VDD2 may include a plurality of second horizontal lines Lx2 and a plurality of second vertical lines Ly2, and the third power line VDD3 may include a plurality of third horizontal lines Lx3 and a plurality of third vertical lines Ly3.

As illustrated in FIGS. 5 to 7, in a unit pixel, the first horizontal line Lx1 of the first power line VDD1 may be disposed on a layer which differs from the first vertical line Ly1, the second horizontal line Lx2 of the second power line VDD2 may be disposed on a layer which differs from the second vertical line Ly2, and the third horizontal line Lx3 of the third power line VDD3 may be disposed on a layer which differs from the third vertical line Ly3.

For example, the first horizontal line Lx1 may be electrically connected to the first vertical line Ly1, and may be insulated from the second and third vertical lines Ly2 and Ly3, the second horizontal line Lx2 may be electrically connected to the second vertical line Ly2, and may be insulated from the first and third vertical lines Ly1 and Ly3, and the third horizontal line Lx3 may be electrically connected to the third vertical line Ly3, and may be insulated from the first and second vertical lines Ly1 and Ly2.

The first to third vertical lines Ly1 to Ly3 may be disposed apart from one another on the same layer in the horizontal direction x and may include the same metal material, but is not limited thereto.

For example, as illustrated, the first to third vertical lines Ly1 to Ly3 may be disposed apart from one another in the horizontal direction x on the first planarization layer 310 covering the plurality of transistors ST1, ST2, and DT included in a unit pixel.

The first to third vertical lines Ly1 to Ly3 may be electrically connected to the driving transistors DT of the first to third subpixels SP1 to SP3, respectively, disposed in a unit pixel.

In detail, the first vertical line Ly1 may be electrically connected to the driving transistor DT included in the first subpixel SP1 of a unit pixel. For example, the first vertical line Ly1 may be electrically connected to the driving transistor DT of the first subpixel SP1 via the first switching transistor ST1 of the first subpixel SP1.

The second vertical line Ly2 may be electrically connected to the driving transistor DT included in the second subpixel SP2 of a unit pixel. For example, the second vertical line Ly2 may be electrically connected to the driving transistor DT of the second subpixel SP2 via the first switching transistor ST1 of the second subpixel SP2.

The third vertical line Ly3 may be electrically connected to the driving transistor DT included in the third subpixel SP3 of the unit pixel. For example, the third vertical line Ly3 may be electrically connected to the driving transistor DT of the third subpixel SP3 via the first switching transistor ST1 of the third subpixel SP3.

Moreover, the first to third horizontal lines Lx1 to Lx3 may be disposed on the same layer in a unit pixel and may be spaced apart from one another in the vertical direction y, and moreover, may include the same metal material. The first to third vertical lines Ly1 to Ly3 may include the same material or different materials.

For example, the first to third horizontal lines Lx1 to Lx3 may be disposed apart from one another in the vertical direction y on the second planarization layer 320.

The first to third horizontal lines Lx1 to Lx3 may be electrically connected to the first to third vertical lines Ly1 to Ly3 at the first to third contact points CP1 to CP3, respectively.

In detail, the first horizontal line Lx1 may be electrically connected to the first vertical line Ly1 at the first contact point CP1 of the unit pixel. For example, as illustrated in FIGS. 5 to 7, the first horizontal line Lx1 and the first vertical line Ly1 may be electrically connected to each other through a first contact point connection electrode CP1e passing through the second planarization layer 320, at the first contact point CP1.

The second horizontal line Lx2 may be electrically connected to the second vertical line Ly2 at the second contact point CP2 of the unit pixel. For example, as illustrated in FIG. 5, the second horizontal line Lx2 and the second vertical line Ly2 may be electrically connected to each other through a second contact point connection electrode CP2e passing through the second planarization layer 320, at the second contact point CP2.

The third horizontal line Lx3 may be electrically connected to the third vertical line Ly3 at the third contact point CP3 of the unit pixel. For example, as illustrated in FIG. 5, the third horizontal line Lx3 and the third vertical line Ly3 may be electrically connected to each other through a third contact point connection electrode CP3e passing through the second planarization layer 320, at the third contact point CP3.

Each of the first to third contact points CP1 to CP3 may overlap the bank 500 defining the emission region of a corresponding one of the first to third subpixels SP1 to SP3. For example, as illustrated in FIG. 5, the first to third contact point connection electrodes CP1e, CP2e, and CP3e may be disposed to overlap the bank region BA. For example, the first to third contact point connection electrodes CP1e, CP2e, and CP3e may be disposed to overlap a lower portion of the bank 500.

For example, the plurality of power lines electrically disconnected from one another may be respectively connected to the plurality of subpixels emitting lights of different colors, and the plurality of driving voltages of different levels may be supplied through the plurality of power lines. For example, the power supply may supply a first driving voltage through the first power line and supply a second driving voltage, having a level differing from a level of the first driving voltage, through the second power line.

Various examples and aspects of the present disclosure are described below. These are provided as examples, and do not limit the scope of the present disclosure.

In one or more examples, a display apparatus may include: a first subpixel configured to emit light of a first color; a second subpixel configured to emit light of a second color different from the first color; and a power supply configured to provide a first driving voltage to a first power line connected to the first subpixel and provide a second driving voltage to a second power line connected to the second subpixel. The first power line may include a plurality of first power lines (e.g., a first horizontal line and a first vertical line), and the second power line may include a plurality of second power lines (e.g., a second horizontal line and a second vertical line). The plurality of first power lines are connected to each other. The plurality of second power lines may be connected to each other. The plurality of first power lines may be electrically disconnected from the plurality of second power lines. The first driving voltage may have a level different from a level of the second driving voltage.

In an example, a unit pixel may include the first subpixel and the second subpixel. Each of the first subpixel and the second subpixel may include a driving transistor and a light emitting device. Each driving transistor may have a drain electrode and a source electrode. Each light emitting device may have an anode electrode and a cathode electrode. In an example, a drain electrode may refer to a source electrode and vice versa. In an example, an anode electrode may refer to a cathode electrode and vice versa. In an example, a period during which a subpixel (e.g., the first subpixel or the second subpixel) is driven may include an initialization period and an emission period. The emission period may be a period during which the subpixel emits light. The initialization period may be a period for preparation for enabling the subpixel to emit light. The initialization period may precede the emission period.

In an example, the first driving voltage may be supplied to the first subpixel as a voltage having a highest absolute value among voltages supplied to the first subpixel. The first driving voltage may be supplied to the driving transistor of the first subpixel as a voltage having a highest absolute value among voltages supplied to the driving transistor of the first subpixel. The first driving voltage may be supplied to the drain electrode or the source electrode of the driving transistor of the first subpixel as a voltage having a highest absolute value among voltages supplied to the drain electrode or the source electrode, respectively, of the driving transistor of the first subpixel. The first driving voltage may be supplied to the anode electrode of the light emitting device of the first subpixel as a voltage having a highest absolute value among voltages supplied to the anode electrode of the light emitting device of the first subpixel. The first driving voltage may be supplied during the initialization period, the emission period, or both periods.

In an example, the second driving voltage may be supplied to the second subpixel as a voltage having a highest absolute value among voltages supplied to the second subpixel. The second driving voltage may be supplied to the driving transistor of the second subpixel as a voltage having a highest absolute value among voltages supplied to the driving transistor of the second subpixel. The second driving voltage may be supplied to the drain electrode or the source electrode of the driving transistor of the second subpixel as a voltage having a highest absolute value among voltages supplied to the drain electrode or the source electrode, respectively, of the driving transistor of the second subpixel. The second driving voltage may be supplied to the anode electrode of the light emitting device of the second subpixel as a voltage having a highest absolute value among voltages supplied to the anode electrode of the light emitting device of the second subpixel. The second driving voltage may be supplied during the initialization period, the emission period, or both periods.

In an example, the display apparatus may include a plurality of unit pixels having first subpixels and second subpixels. Each of the first subpixels may correspond to or comprise the first subpixel, and each of the second subpixels may correspond to or comprise the second subpixel. Thus, the first power line may be connected to the first subpixels, and the second power line may be connected to the second subpixels.

As described above, in an example embodiment of the present disclosure, the first to third power lines VDD1 to VDD3 electrically disconnected from one another may be respectively connected to the first to third subpixels SP1 to SP3 emitting lights of different colors, and the first to third driving voltages V1 to V3 of different levels may be supplied through the first to third power lines VDD1 to VDD3, and thus, the power consumption of the display apparatus may be reduced, and a degradation in the driving transistor DT included in each of the first to third subpixels SP1 to SP3 may be reduced.

In an example embodiment of the present disclosure, each of the first to third power lines VDD1 to VDD3 may have a mesh structure line, and thus, even when a portion of each of the first to third power lines VDD1 to VDD3 is open-circuited by a foreign material, the first to third driving voltages V1 to V3 may be stably supplied to the first to third subpixels SP1 to SP3, thereby stably driving a display apparatus.

In one or more example embodiments of the present disclosure, first and second power lines electrically disconnected from each other may be connected to first and second subpixels which emit lights of different colors, and first and second driving voltages which differ may be supplied through the first and second power lines, and thus, the power consumption of a display apparatus may decrease, and a degradation in a driving transistor included in each of the first and second subpixels may be prevented or mitigated.

In one or more example embodiments of the present disclosure, because each of the first and second power lines includes a mesh structure line, even when a portion of each of the first and second power lines is open-circuited by a foreign material, the first and second driving voltages may be supplied to the first and second subpixels, and thus, the display apparatus may be stably driven.

In one or more aspects, example embodiments of the present disclosure may decrease the power consumption of the display apparatus, thereby supporting ESG initiatives.

The effects according to the present disclosure are not limited to the above examples, and other various effects may be included in the specification.

The description herein has been presented to enable any person skilled in the art to make, use and practice the technical features of the present disclosure, and has been provided in the context of one or more particular example applications and their example requirements. Various modifications, additions and substitutions to the described embodiments will be readily apparent to those skilled in the art, and the principles described herein may be applied to other embodiments and applications without departing from the scope of the present disclosure. The description herein and the accompanying drawings provide non-limiting examples of the technical features of the present disclosure for illustrative purposes. In other words, the disclosed embodiments illustrate the scope of the technical features of the present disclosure and are not intended to be limiting in any respect. Thus, the scope of the present disclosure is not limited to the embodiments shown, but is to be accorded the widest scope consistent with the claims and their equivalents.

What is claimed is:

1. A display apparatus, comprising:
a display panel including a plurality of unit pixels, each unit pixel including a first subpixel for emitting light of a first color and a second subpixel for emitting light of a second color different from the first color; and
a power supply configured to supply a first driving voltage through a first power line connected to the first subpixels of the plurality of unit pixels and to supply a second driving voltage through a second power line connected to the second subpixels of the plurality of unit pixels,
wherein:
each of the first power line and the second power line comprises a mesh structure line;
the mesh structure line of one of the first power line and the second power line is electrically disconnected from the mesh structure line of another one of the first power line and the second power line; and
the first driving voltage has a level different from a level of the second driving voltage.

2. The display apparatus of claim 1, wherein:
the mesh structure line of the first power line is connected to the first subpixels and comprises a plurality of first horizontal lines parallel to a horizontal direction of the display panel and a plurality of first vertical lines parallel to a vertical direction of the display panel; and
the mesh structure line of the second power line is connected to the second subpixels and comprises a plurality of second horizontal lines parallel to the horizontal direction of the display panel and a plurality of second vertical lines parallel to the vertical direction of the display panel.

3. The display apparatus of claim 2, wherein:
the plurality of first horizontal lines and the plurality of first vertical lines of the first power line are electrically connected to each other;
the plurality of second horizontal lines and the plurality of second vertical lines of the second power line are electrically connected to each other; and
each of the plurality of first horizontal lines and the plurality of first vertical lines is insulated from each of the plurality of second horizontal lines and the plurality of second vertical lines.

4. The display apparatus of claim 2, wherein:
the plurality of first horizontal lines are disposed on a layer that is different from a layer on which the plurality of first vertical lines are disposed; and
the plurality of second horizontal lines are disposed on a layer that is different from a layer on which the plurality of second vertical lines are disposed.

5. The display apparatus of claim 2, wherein one of the plurality of first vertical lines and one of the plurality of second vertical lines are disposed on a same layer in a unit pixel and are spaced apart from each other in the horizontal direction.

6. The display apparatus of claim 2, wherein one of the plurality of first horizontal lines and one of the plurality of second horizontal lines are disposed on a same layer in a unit pixel and are spaced apart from each other in the vertical direction.

7. The display apparatus of claim 2, wherein:
one of the plurality of first vertical lines and one of the plurality of second vertical lines are disposed apart from each other on a first planarization layer covering a plurality of transistors included in a unit pixel; and
one of the plurality of first horizontal lines and one of the plurality of second horizontal lines are disposed apart from each other on a second planarization layer covering the one of the plurality of first vertical lines, the one of the plurality of second vertical lines, and the first planarization layer.

8. The display apparatus of claim 2, wherein:
each of the plurality of unit pixels comprises a first contact point and a second contact point;
at each first contact point, a corresponding one of the plurality of first horizontal lines and a corresponding one of the plurality of first vertical lines cross each other and are electrically connected to each other; and
at each second contact point, a corresponding one of the plurality of second horizontal lines and a corresponding one of the plurality of the second vertical lines cross each other and are electrically connected to each other.

9. The display apparatus of claim 8, wherein each of the first and second contact points overlaps a bank defining an emission region of a corresponding one of the first and second subpixels.

10. The display apparatus of claim 8, wherein:
at each first contact point, the corresponding one of the plurality of first horizontal lines and the corresponding one of the plurality of first vertical lines are electrically connected to each other through a second planarization layer; and
at each second contact point, the corresponding one of the plurality of second horizontal lines and the corresponding one of the plurality of the second vertical lines are electrically connected to each other through the second planarization layer.

11. The display apparatus of claim 8, wherein:
a respective one of the plurality of first horizontal lines is insulated from a respective one the plurality of second vertical lines at an intersection point therebetween in each of the plurality of unit pixels; and
a respective one of the plurality of second horizontal lines is insulated from a respective one of the plurality of first vertical lines at an intersection point therebetween in each of the plurality of unit pixels.

12. The display apparatus of claim 1, wherein:
each first subpixel comprises a light emitting device for emitting red light, and each second subpixel comprises a light emitting device for emitting green light;
the power supply is configured to supply the first driving voltage to the light emitting devices of the first subpixels, and supply the second driving voltage to the light emitting devices of the second subpixels; and
the level of the first driving voltage is lower than the level of the second driving voltage.

13. The display apparatus of claim 2, wherein:
each of the plurality of unit pixels comprises a third subpixel;
each of the third subpixels of the plurality of unit pixels includes a light emitting device for emitting light of a third color different from the first and second colors;
the power supply is further configured to supply a third driving voltage, having a level different from the level of each of the first and second driving voltages, to the light emitting devices of the third subpixels through a third power line; and
the third power line comprises a mesh structure line electrically disconnected from the first and second power lines.

14. The display apparatus of claim 13, wherein:
the level of each of the first, second and third driving voltages is set based on a saturation voltage of a driving transistor included in a corresponding one of the first, second and third subpixels;
the first driving voltage is higher than or equal to the saturation voltage of the driving transistor of the corresponding one of the first subpixels;
the second driving voltage is higher than or equal to the saturation voltage of the driving transistor of the corresponding one of the second subpixels; and
the third driving voltage is higher than or equal to the saturation voltage of the driving transistor of the corresponding one of the third subpixels.

15. The display apparatus of claim 13, wherein the mesh structure line of the third power line is connected to the third subpixels and comprises a plurality of third horizontal lines parallel to the horizontal direction of the display panel and a plurality of third vertical lines parallel to the vertical direction of the display panel.

16. The display apparatus of claim 15, wherein:
the plurality of third horizontal lines and the plurality of third vertical lines of the third power line are electrically connected to each other;
the plurality of third horizontal lines are insulated from the plurality of first horizontal lines and the plurality of second horizontal lines; and
the plurality of third vertical lines are insulated from the plurality of first vertical lines and the plurality of second vertical lines.

17. The display apparatus of claim 15, wherein:
the plurality of third horizontal lines are disposed on a layer that is different from a layer on which the plurality of third vertical lines are disposed;
the plurality of third horizontal lines are disposed on a same layer as the plurality of first horizontal lines and the plurality of second horizontal lines;
the plurality of third horizontal lines are spaced apart from one another in the vertical direction;
the plurality of third horizontal lines are disposed apart from the plurality of first horizontal lines and the plurality of second horizontal lines in the vertical direction; and
the plurality of third horizontal lines are disposed on a second planarization layer covering the plurality of first, second and third vertical lines and a first planarization layer covering a plurality of transistors included in a unit pixel.

18. The display apparatus of claim 15, wherein:
the plurality of third vertical lines are disposed on a same layer as the plurality of first and second vertical lines in the plurality of unit pixels;
the plurality of third vertical lines are spaced apart from one another in the horizontal direction; and
the plurality of third vertical lines are disposed apart from the plurality of first and second vertical lines on a first planarization layer covering a plurality of transistors included in the plurality of unit pixels.

19. The display apparatus of claim 15, wherein:
each of the plurality of unit pixels further comprises a third contact point;
at each third contact point, a corresponding one of the plurality of third horizontal lines and a corresponding one of the plurality of third vertical lines intersect;
each third contact point overlaps a bank defining an emission region of a corresponding one of the third subpixels;
at each third contact point, the corresponding one of the plurality of third horizontal lines and the corresponding one of the plurality of third vertical lines are electrically connected to each other through a second planarization; and
a respective one of the plurality of third horizontal lines is insulated from a respective one of the plurality of first vertical lines at a point intersecting the respective one of the plurality of first vertical lines and insulated from a respective one of the plurality of second vertical lines at a point intersecting the respective one of the plurality of second vertical lines, in each of the plurality of unit pixels.

20. The display apparatus of claim 13, wherein:
the light of the third color is blue light; and
the level of the third driving voltage is higher than the level of each of the first and second driving voltages.
